(19) United States
(12) Patent Application Publication
(10) Pub. No.: US 2014/0251214 A1
(43) Pub. Date: Sep. 11, 2014

(54) HEATED SUBSTRATE SUPPORT WITH FLATNESS CONTROL

(71) Applicant: APPLIED MATERIALS, INC., Santa Clara, CA (US)

(72) Inventors: OLKAN CUVALCI, Sunnyvale, CA (US); GWO-CHUAN TZU, Sunnyvale, CA (US); XIAOXIONG YUAN, San Jose, CA (US)

(73) Assignee: APPLIED MATERIALS, INC., Santa Clara, CA (US)

(21) Appl. No.: 13/787,385

(22) Filed: Mar. 6, 2013

(51) Int. Cl. H01L 21/683; G01K 3/10

(52) U.S. Cl. CPC H01L 21/683; G01K 3/10
USPC 118/712; 374/102; 118/500

(57) ABSTRACT

Embodiments of heated substrate supports are provided herein, In some embodiments, a heated substrate support includes a support plate having a top surface and an opposite bottom surface; and a first heater disposed within the support plate, wherein the first heater is disposed beneath a mid-plane of the support plate, and wherein the first heater is disposed proximate a central zone of the support plate.

### FIELD

Embodiments of the present invention generally relate to semiconductor processing equipment.

### BACKGROUND

Common methods of semiconductor fabrication, for example atomic layer deposition (ALD) and chemical vapor deposition (CVD), often take place in process chambers at elevated temperatures. The process chamber typically includes a substrate support to support a substrate a surface of the substrate support. A backside pressure may be created in a space disposed between the substrate support and the substrate.

The substrate supports are usually as large, or larger, than the substrate supported thereon. In many cases, substrate supports are formed from metallic materials. Some substrate supports include one or more heater elements to facilitate the process taking place in the chamber. The heater elements heat the substrate support which in turn directly or indirectly heats the substrate.

For some semiconductor fabrication procedures, the chamber temperature and the heater element(s) affects the substrate support, making it more susceptible to deflection under the weight of the substrate support and the heater element(s). The deflection typically increases radially from the center of the substrate support, reaching a maximum at the perimeter of the plate.

The inventors have observed that under certain conditions, the substrate support deflection is sufficient to cause separation between portions of the substrate and the substrate support, causing leakage of the backside pressure, adversely affecting the process.

Therefore, the inventors have provided embodiments of substrate supports having improved flatness control.

### SUMMARY

Embodiments of heated substrate supports are provided herein, In some embodiments, a heated substrate support includes a support plate having a top surface and an opposite bottom surface; and a first heater disposed within the support plate, wherein the first heater is disposed beneath a mid-plane of the support plate, and wherein the first heater is disposed proximate a central zone of the support plate.

In some embodiments, a heated substrate support includes a support plate having a top surface and an opposite bottom surface; a shaft coaxial with the support plate and coupled to the bottom surface; a first heater disposed within a central zone of the support plate beneath a mid-plane of the support plate; a second heater disposed within a second zone of the support plate beneath the mid-plane of the support plate; a first sensor to provide data corresponding to a temperature in the first zone; and a second sensor to provide data corresponding to a temperature in the second zone.

In some embodiments, a method for controlling the flatness of a substrate support is provided. In some embodiments, the method includes energizing a heater element disposed within a support plate of the substrate support and beneath a mid-plane of the support plate; sensing a temperature of a central zone within the support plate; comparing the temperature of the central zone with a predetermined temperature corresponding to a thermal expansion of a portion of the support plate; and deenergizing the heater element if the sensed temperature is equal to or greater than the predetermined temperature.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a perspective view of a substrate support suitable for use with embodiments of the present invention.

FIG. 2 depicts a sectional side view of a substrate support according to some embodiments of the present invention.

FIG. 3 depicts a method for controlling the flatness of a substrate support according to embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention generally relate to substrate supports providing support to a substrate during processing. The inventive apparatus and method provide a substrate support with a surface flatness that can be controlled during processing. The improved flatness of the inventive apparatus may advantageously reduce or eliminate separation of the substrate support from the substrate and the consequent leakage of backside pressure.

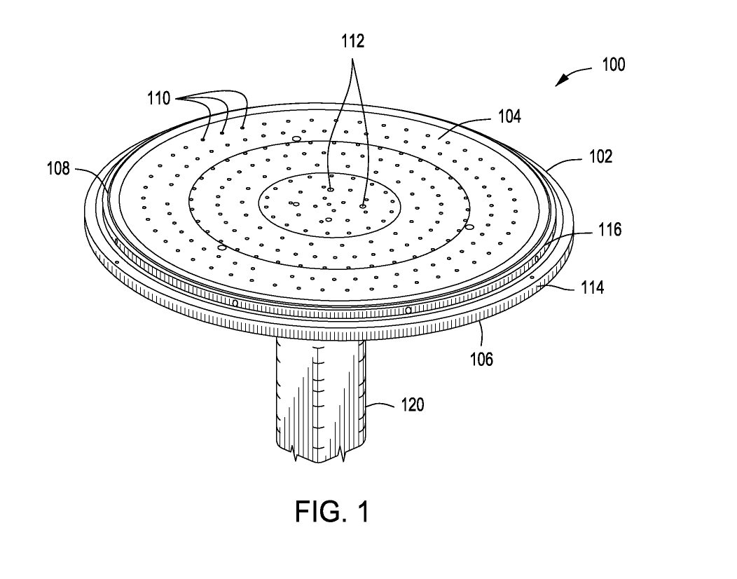

FIG. 1 depicts a substrate support 100 for substrate processing comprising a support plate 102 for providing support to the substrate. In some embodiments, the support plate 102 can be fabricated from aluminum or an aluminum alloy, such as aluminum 6061 or other aluminum alloys. The plate may comprise a top surface 104 and an opposite bottom surface 106. A raised edge 108 and a plurality of protrusions or bumps 110 may provide support for the perimeter and internal regions, respectively, of the substrate (not shown). The support plate may include holes 112 which provide a vacuum to form a pressure condition on the backside of the substrate to assist in holding the substrate to the support plate 102 as in, for example, a vacuum chuck. Alternately, holes 112 may provide a gas to form a pressure condition to the backside of the substrate to facilitate thermal transfer between the substrate and the substrate support 100 as in, for example, an electrostatic chuck. In either case, in forming the pressure condition, the vacuum or gas may be provided through the holes 112 as illustrated or through channels, or other features in the plate, through the plate, or on the substrate support surface 104.

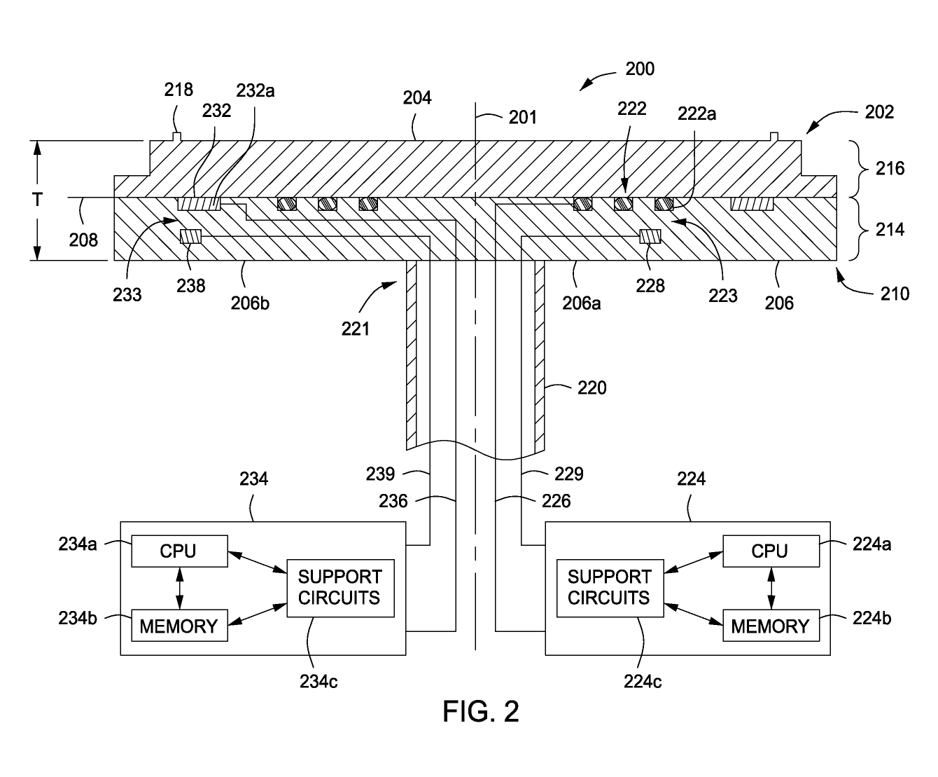

Some substrate supports may be formed from two or more component plates, for example bottom plate 114 and top plate 116 which may be joined together using, for instance, mechanical fasteners or metal joining techniques, such a welding or brazing. The support plates 102 have one or more heater elements (shown in FIG. 2) within the support plate 102 to heat the substrate placed thereon. The heater element(s) may be placed in an appropriately configured portion of an interface between the bottom plate 114 and the top plate 116 prior to joining the plates together.

The support plate may be mounted to a shaft 120. In some embodiments, the shaft 120 may be fixed. In some embodiments, the shaft may be movable to provide vertical and/or rotational positioning of the substrate supported on the support plate 102 relative to the process chamber.

FIG. 2 depicts a cross sectional view of a substrate support 200 with a support plate 202 in accordance with some embodiments of the present invention. Support plate 202 comprises a top surface 204 and an opposite bottom surface 206, and a thickness T between the top and bottom surfaces 204, 206 respectively. A mid-plane 208 bisects, or substantially bisects, the thickness T creating a bottom portion 214 and a top portion 216 having equal, or substantially equal, thickness. In embodiments in which the mid-plane 208 does not bisect the thickness T of the support plate 202, the top portion 216 is thicker than the bottom portion 214.

The bottom portion 214 and the top portion 216 may be separate pieces and may be joined together, for example with mechanical fasteners or by metal-joining operations such as welding or brazing, to form the support plate 202. At least one of the bottom portion 214 or the top portion 216 include a perimeter edge 210.

The substrate support includes shaft 220 coupled to the bottom surface 206. In some embodiments, as illustrated in FIG. 2, the shaft 220 may be directly affixed at the first end 221 to the bottom surface 206. Typically, the shaft and the support plate 202 are coaxially arranged. The shaft 220 supports the central portion of the support plate 202 against any downward deflection. Deflection of the support plate 202 has been observed as radially increasing from the centerline 201 of the support. The inventors have also noted that mass added to the bottom surface 206 of the support plate 202 may increases the undesirable downward deflection of the support plate 202 under some conditions. Accordingly, in embodiments of the present invention, the shaft 220 is affixed to the bottom surface 206 without additional plates between the shaft and the plate.

The support plate 202 may include a first heater 222 to heat a central zone 223 as illustrated in FIG. 2. The first heater 222 may be any type of heater suitable to heat the support plate 202 to a desired temperature or within a desired range of temperatures. For example, in some embodiments, the first heater 222 may comprise one or more coils of a resistive heating element 222a.

In some embodiments, a first controller 224, or computer, may comprise a central processing unit (CPU) 224a, a memory 224b, and support circuits 224c. The first controller 224 may be one of any form of general purpose computer processor that can be used in an industrial setting for controlling various industrial processes. The first controller 224 may control a power source, for example an AC or DC power source, to power, the first heater 222. The first controller 224 may be coupled to the heater (e.g., to the power source of the heater) via a connection line 226 to energize the first heater 222 to facilitate heating the central zone 223 of the support plate 202 to a predetermined temperature or to within a range of temperatures. The connection line 226 may be an power line to energize the first heater 222, for example an electrical power line to supply electrical energy to a resistive heater. Other types of heaters may require different types of connection lines to energize the first heater 222.

In some embodiments, a first sensor 228 is disposed within the support plate 202 to provide data to the first controller 224 via first communication channel 229. The data communicated may include data corresponding to a temperature of the central zone 223 of the substrate support. In some embodiments, the central zone 223 includes a portion 206a of the bottom surface 206.

The support plate 202 may include a second heater 232 to heat a second zone 233 of the support plate 202 as illustrated in FIG. 2. The second heater 232 may be of any type as described above. In some embodiments, the second heater 232 may comprise one or more ring-like coils (one shown) of a resistive heating element 232a.

As illustrated, heating elements of the first and second heaters 222 and 232 are symmetric about the center line 201 of the support plate 202, although symmetry is not required. The first heater 222 is positioned proximate to the centerline 201 while the second heater 232 is proximate the perimeter edge 210. Relative to the centerline, the first heater 222 is an inner element, and central zone 223 is a first, or inner zone. Similarly, second heater 232 is an outer element and second zone 233 is an outer zone. Inner heater element (or zone) and outer heater element (or zone) as used herein relate to the relative position with respect to the centerline and the other heater element (or zone). In some embodiments, the first and second heaters 222 and 232 are of the same type or construction; in other embodiments, the first and second heaters 222 and 232 are of different types, such as a first being a resistive heater element and a second carrying a heating medium.

In some embodiments, a second controller 234, or computer, may comprise a central processing unit (CPU) 234a, a memory 234b, and support circuits 234c as described above. Similar to the first controller discussed above, the second controller 234 may be coupled to the heater via a connection line 236 to energize the second heater 232 to facilitate heating the second zone 233 of the support plate 202 to a predetermined temperature or to within a range of temperatures. The connection line 236 may be an electrical power line or other type of connection line as required to energize the second heater 232.

In some embodiments, a second sensor 238 may be disposed within the support plate 202 to provide data to the second controller 234 via second communications channel 239. The data communicated may include data corresponding to a temperature of a second zone 233 of the substrate support. In some embodiments, the second zone 233 is an outer zone. In some embodiments, the second zone 233 includes a portion 206b of the bottom surface 206.

The first and second controllers 224, 234 may be separate controllers as illustrated, or they may be a single controller, for example a master controller.

The first controller 224 may be functionally coupled to various components of the support plate 202. Specifically, the controller may be coupled to the first sensor 228 to communicate data such that the controller can determine the temperature of the central zone 223. The controller may further record and/or analyze the substrate temperature, once determined. The second controller 234 and the second sensor 238 may be functionally coupled in a similar manner.

As illustrated in FIG. 2, the first and second heaters 222, 232 are placed between the mid-plane 208 and the bottom surface 206. This places the heater element(s) of the first and second heaters 222, 232 closer to the bottom surface 206 than to the top surface 204.

First and second sensors 228, 238 are illustrated in first (e.g., central) and second (e.g., outer) zones 223 and 233, respectively for ease of illustration only. More than two sensors can be used, and they may be placed at various locations to beneficially sense and provide the temperature of a portion of the support plate 202, for example the temperature adjacent to the bottom surface 206.

The inventors have noted that by placing the heater element(s) below the mid-plane 208, the heater element(s) (e.g., 222, 232) produce a higher temperature at the bottom surface 206 than at the top surface 204 of the support plate 202. Surprisingly, this placement beneficially influences the flatness of the support plate 202. The inventors have found that the higher temperature at the bottom surface 206 advantageously produces a greater thermal expansion of the bottom surface 206 when compared to the expansion of the top surface 204.

The greater expansion of the bottom surface 206 compared to the expansion of the top surface 204 results in the perimeter edge 210 deflecting upward, that is, the difference in expansion induces a concave up deflection of the support plate 202.

The concave up or upward deflection is opposite in direction to the natural tendency of the perimeter edge 210 of the support plate 202 to deflect downwards, due to the weight of the support plate 202. The natural downward deflection of the support plate 202 is intensified when the plate is used at elevated temperatures.

Under some conditions, the inventors have noted that the natural downward deflection of the support plate 202 is pronounced enough that the raised rim 218 of the support plate 202 does not effectively seal against the backside of the substrate, resulting in loss of backside pressure. The separation may be significant when the support plate is used in an elevated temperature environment. Moreover, the inventors have observed that substrate supports fabricated from aluminum are more susceptible to excessive droop when heated, thus benefitting even more greatly from embodiments of the present invention.

The inventors have discovered that by controlling the temperature, or range of temperatures, of the bottom surface 206 of the support plate 202, the effects of the natural deflection of the inventive substrate support can be minimized or eliminated. By controlling the temperature of the bottom portion 214, comprising the bottom surface 206, the thermal expansion of the bottom portion 214 can be controlled. Controlling the thermal expansion of the bottom portion 214 in turn controls the upward deflection of the support plate 202, for example, at the perimeter edges 210.

In general, the deflection, whether the natural downward deflection or the induced upward deflection of the support plate 202, increases radially from the centerline 201. In countering the downward deflection of the support plate 202 by creating a predictable and controllable upward deflection caused by the thermal expansion of the bottom portion 214, or the bottom surface 206, of the support plate 202, the inventors have been able to better maintain the flatness of the support plate 202 and consequently have been effective in maintaining the backside pressure on the substrate supported on the support plate 202.

The inventors have determined appropriate bottom surface 206 temperatures, or ranges of temperatures, for the support plate 202 when operating in elevated temperature environments. The temperature, or range of temperatures, of the zone corresponds to a temperature of the bottom portion 214 of the support plate 202. The bottom portion includes bottom surface 206. At an identified temperature or range of temperatures, the bottom surface 206 demonstrates desired characteristics. For example, at an identified temperature or temperature range, the corresponding thermal expansion of the bottom surface 206 is predictable and controllable to counter the natural downward deflection of the perimeter edge 210 in the particular temperature environment in which the plate is used. The temperature or range of temperatures for a zone (e.g., 223 or 233) that results in the desired plate characteristics (for example upward deflection of perimeter edge 210) may vary depending upon the conditions of the temperature environment in which the support plate 202 is used. This information can be stored in the first and second controllers 224, 234, for example in memory 224b, 234b for various temperature environments.

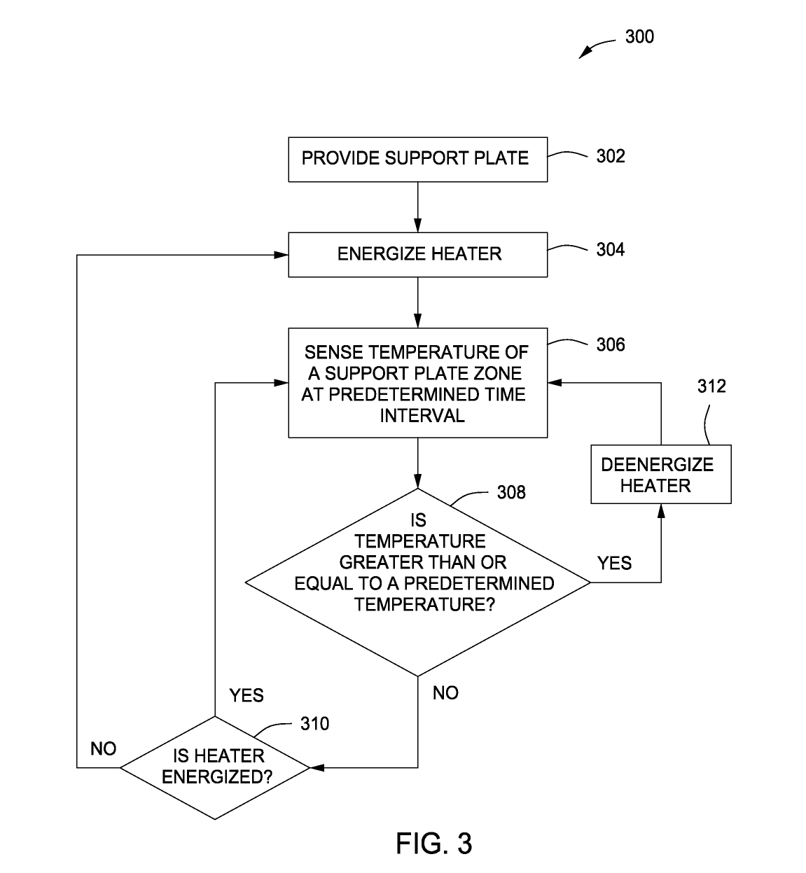

FIG. 3 depicts a method for the control of the temperature of a zone of a substrate support in accordance with embodiments of the present invention. At 302, a substrate support having a support plate 202 is provided. The substrate support may be provided in a process chamber (not shown). The support plate 202 has at least one heater, for example first heater 222, disposed below the mid-plane 208 of the support plate 202 and at least one sensor, for example first sensor 228, in a zone, for example center zone 223, of the support plate 202.

At 304, the heater (e.g., 222) is energized to provide heat to a zone in the support plate 202, for example zone 223. Energizing the heater may include providing electric power, or another energy source, to the heater.

At 306, the temperature of a zone, for example central zone 223, of the support plate 202 is sensed at a predetermined time interval. The predetermined time interval may vary, depending on process conditions such as the initial temperature of the support plate 202, the desired final temperature of the support plate, or the like. In some embodiments, the sensed temperature may be stored in the first controller 224, for example in a memory 224b.

Next at 308, a query is made as to whether the sensed temperature is equal to or greater than (i.e., less than) a predetermined temperature. The predetermined temperature may be dictated by a number of process conditions such as, the initial temperature of the support plate, the ambient temperature, or the maximum process temperature anticipated, or the like. The predetermined temperature may be a range of temperatures within which the support plate, particularly the bottom portion 214 of the support plate 202, demonstrates desired characteristics, for example thermal expansion.

If the query is answered in the negative, a further query is made at 310 as to whether the first heater 222 is energized. If the heater is energized, the temperature of the zone is sensed at a predetermined interval at 306.

If the answer at 310 is in the negative, the heater is energized at 304.

If the query of 308 is answered in the affirmative, 312 deenergizes the first heater 222, or reduces the energy supplied to the heater, and returns to 306 where the temperature of a zone in the support plate is sensed at a predetermined time interval, followed by 308. The series of operations may continue until interrupted, for example by an end of process signal at the end of a predetermined length of process time or other internal or external end-of-process signal.

While the foregoing is directed to embodiments of the present invention, other and further embodiments of the invention may be devised without departing from the basic scope thereof.

1. A heated substrate support, comprising:
a support plate having a top surface and an opposite bottom surface; and
a first heater disposed within the support plate, wherein the first heater is disposed beneath a mid-plane of the support plate, and wherein the first heater is disposed proximate a central zone of the support plate.

2. The heated substrate support of claim 1, further comprising:
a second heater disposed within the support plate between the mid-plane and the bottom surface in a second zone independent of the central zone.

3. The heated substrate support of claim 1, further comprising:
a first sensor to provide data corresponding to a temperature in the central zone.

4. The heated substrate support of claim 3, further comprising:
a first controller coupled to the first sensor and the first heater to control the temperature of the central zone in response to the data provided by the first sensor.

5. The heated substrate support of claim 4, further comprising:
a second heater disposed within the support plate between the mid-plane and the bottom surface in a second zone independent of the central zone; and
a second sensor to provide data corresponding to a temperature of the second zone.

6. The heated substrate support of claim 5, further comprising:
a second controller coupled to the second sensor and the second heater to control the temperature of the second zone in response to the data provided by the second sensor.

7. The heated substrate support of claim 6, wherein the first controller and the second controller are the same controller.

8. The heated substrate support of claim 5, wherein the second zone comprises an outer zone.

9. The heated substrate support of claim 5, wherein the first heater and the second heater are substantially coplanar.

10. The heated substrate support of claim 1, wherein the support plate comprises a top plate coupled to a bottom plate, wherein the first heater is disposed in a channel formed in at least one of the top plate or the bottom plate.

11. The heated substrate support of claim 10, wherein the top plate is at least as thick as the bottom plate, and wherein the first heater is disposed in a channel formed in the bottom plate.

12. The heated substrate support of claim 1, wherein the support plate is fabricated from aluminum or an aluminum alloy.

13. The heated substrate support of claim 1, further comprising:
a shaft coupled to the support plate.

14. The heated substrate support of claim 13, wherein the shaft is directly coupled to the support plate.

15. A heated substrate support, comprising:
a support plate having a top surface and an opposite bottom surface;
a shaft coaxial with the support plate and coupled to the bottom surface;
a first heater disposed within a central zone of the support plate beneath a mid-plane of the support plate;
a second heater disposed within a second zone of the support plate beneath the mid-plane of the support plate;
a first sensor to provide data corresponding to a temperature in the central zone; and
a second sensor to provide data corresponding to a temperature in the second zone.

16. The heated substrate support of claim 15, further comprising:
one or more controllers coupled to the first and second sensors and the first and second heaters to respectively and independently control the temperature of the central zone in response to the data provided by the first sensor and the temperature of the second zone in response to the data provided by the second sensor.

17. The heated substrate support of claim 15, wherein the support plate comprises a top plate coupled to a bottom plate, wherein the first heater is disposed in a channel formed in at least one of the top plate or the bottom plate.

18. The heated substrate support of claim 17, wherein the top plate is at least as thick as the bottom plate, and wherein the first heater is disposed in a channel formed in the bottom plate.

19. A method for controlling the flatness of a substrate support, comprising:
energizing a heater element disposed within a support plate of the substrate support and beneath a mid-plane of the support plate;
sensing a temperature of a central zone within the support plate;
comparing the temperature of the central zone with a predetermined temperature corresponding to a thermal expansion of a portion of the support plate; and
deenergizing the heater element if the sensed temperature is equal to or greater than the predetermined temperature.

20. The method of claim 19, further comprising:
if the sensed temperature is less than the predetermined temperature, determining if the heater element is energized; and
energizing the heater element if the heater element is not energized.
